(19) United States
(12) Patent Application Publication
(10) Pub. No.: US 2011/0155449 A1
(43) Pub. Date: Jun. 30, 2011

(54) SECURING MECHANISM AND ELECTRONIC DEVICE ENCLOSURE USING THE SAME

(75) Inventor: ZI-MING TANG, Shenzhen City (CN)

(73) Assignees: FU TAI HUA INDUSTRY (SHENZHEN) CO., LTD., ShenZhen City (CN); HON HAI PRECISION INDUSTRY CO., LTD., Tu-Cheng (TW)

(21) Appl. No.: 12/911,913

(22) Filed: Oct. 26, 2010

(30) Foreign Application Priority Data
Dec. 30, 2009 (CN) 200910312568.6

(51) Int. Cl. H05K 5/00; H05K 7/14

(52) U.S. Cl. 174/520; 248/213.2

(57) ABSTRACT

A securing mechanism for a component in an electronic device enclosure includes a bracket, a restriction member, and a resilient member. The bracket defines three guide slits on each side along which protrusions of the component slide. The restriction member forms two slide-rails oblique to the guide slits and two locking portions adjacent to the slide-rails. The resilient member is connected to the bracket and the restriction member. When the protrusions of the component slide along the slide-rails, the restriction member moves substantially perpendicular to the guide slit, and the resilient member deforms elastically. When the protrusions slide out of the slide-rails, the elastic force of the resilient member drives the locking portions to lock with the protrusions of the component, thereby securing the component in the securing mechanism.

### BACKGROUND

1. Technical Field

The present disclosure relates to a securing mechanism and an electronic device enclosure using the securing mechanism.

2. Description of Related Art

Electronic devices, such as desktop computers, notebook computers, and digital video disc players, are popular and widely used. An electronic device generally includes an enclosure securing electronic components therein.

A commonly used electronic device enclosure includes a housing and a securing mechanism fixed inside the housing to secure a component. The securing mechanism includes a fixing bracket fixed on a sidewall of the housing, two slide bars formed on opposite sides of the component, and a plurality of screws. The fixing bracket forms two sliding rails corresponding to the slide bars. The slide bars slide on the sliding rails to a desired position, and are then fixed on the sliding rails by the screws to secure the component to the housing. However, installation and removal of the component are inconvenienced by the screws which must be installed or removed individually.

Therefore, there is room for improvement within the art.

### BRIEF DESCRIPTION OF THE DRAWINGS

The components in the drawings are not necessarily drawn to scale, the emphasis placed upon clearly illustrating the principles of the present disclosure. Moreover, in the drawings, like reference numerals designate corresponding parts throughout the several views, and all the views are schematic.

FIG. 1 is an assembled, isometric view of an embodiment of an electronic device enclosure, the electronic device enclosure including a securing mechanism for securing a component in the electronic device enclosure, and the securing mechanism including a release assembly.

FIG. 2 is a partially exploded, isometric view of the electronic device of FIG. 1.

FIG. 3 is exploded, isometric view of the release assembly of FIG. 1.

FIG. 4 is an isometric view of the component received in the securing mechanism of FIG. 1.

FIG. 5 is similar to FIG. 4, but shows the component assembled in the securing mechanism.

FIG. 6 is similar to FIG. 4, but shows the component disassembled from the securing mechanism.

### DETAILED DESCRIPTION

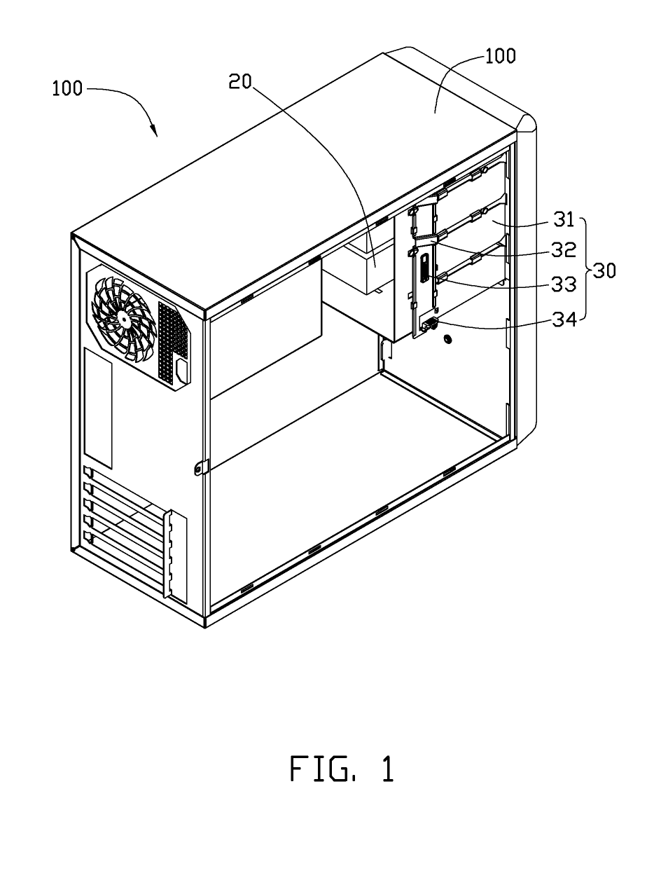

Referring to FIG. 1, an embodiment of an electronic device enclosure 100 includes a housing 10 and a securing mechanism 30 fixed in the housing 10 to secure a component 20 in the housing 10. In the embodiment, the component 20 is a compact disc (CD) drive. Alternatively, the component 20 may be a hard disk or other components.

The housing 10 defines an opening (not shown) in a sidewall. The securing mechanism 30 is fixed in the housing 10 adjacent to the opening, such that the component 20 can be positioned in the securing mechanism 30 from the opening 11.

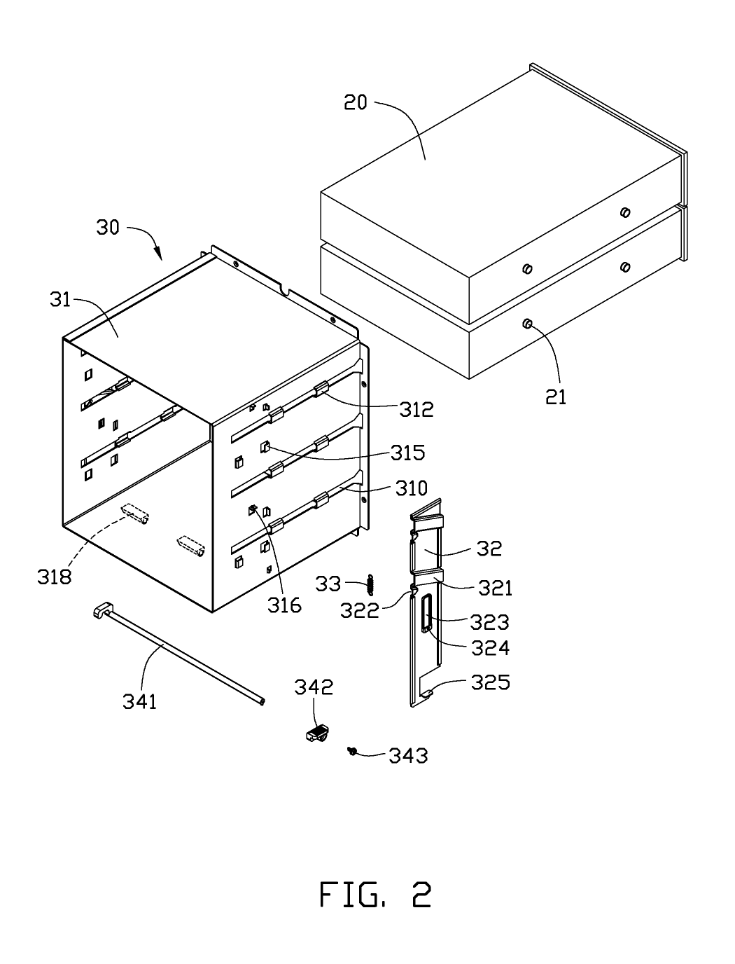

Referring to FIG. 2, the component 20 forms a plurality of protrusions 21 on opposite sidewalls thereof. In the illustrated embodiment, the component 20 forms four protrusions 21 on each side. Alternatively, the component 20 may form one, two, three, five, or any number of protrusions 21 on each side, or form any number of protrusions 21 on one side.

The securing mechanism 30 includes a bracket 31 fixed in the housing 10, a restriction member 32 mounted on the bracket 31, a resilient member 33 connected with the bracket 31 and the restriction member 32, and a release assembly 34 movably positioned on the bracket 31.

The bracket 31 is substantially rectangular and includes four walls connected in order. Opposite sidewalls (not labeled) of the bracket 31 define a plurality of guide slits 310 therein, and also form a number of reinforcement portions 312, a number of pairs of tabs 315, and a fixing portion 316 thereon. The bracket 31 forms a number of assembly portions 318 on a bottom surface (not labeled) which connect the opposite sidewalls.

The guide slits 310 are substantially parallel to the bottom surface. The reinforcement portions 312 extend from the sidewalls, and the tabs 315 and the fixing portion 316 extend from one sidewall. The reinforcement portions 312 are arched and protrude from the sidewalls where the guide slits 310 are defined. The reinforcement portions 312 are connected to opposite sides of the guide slits 310. The tabs 315 are formed adjacent to one end of the guide slits 310. In the illustrated embodiment, the bracket 30 defines three guide slits 310, and forms two reinforcement portions 312 along each guide slit 310. The bracket 30 forms two pairs of tabs 315 which are raised. The fixing portion 316 protrudes from the sidewall and defines a hole (not shown) receiving the resilient member 33. Alternatively, the bracket 30 may define one guide slit 310, and form one reinforcement portion 312 along the guide slit 310 and one pair of tabs 315. The fixing portion 316 may be a protrusion protruding from the sidewall. The reinforcement portions 315 may be omitted.

Each assembly portion 318 defines a shaft hole (not shown) therein to receive the release assembly 34. In the illustrated embodiment, the bracket 30 forms two assembly portions 318, and may form one, three, or more assembly portions 318. The assembly portions 318 may alternatively be raised.

The restriction member 32 is a substantially rectangular plate. The restriction member 32 forms two slide-rails 321 and two locking portions 322 adjacent to and corresponding to the number of the slide-rails 321. The restriction member 32 further defines a receiving cutout 323 along its longitudinal axis and a connection hole 324 adjacent to one end of the receiving cutout 323 and away from the slide-rails 321. The restriction member 32 forms a resisting portion 325 at one end away from the slide-rails 321. In the illustrated embodiment, the slide-rails 321 are not parallel to the elevational axis of the restriction member 32, one end of each slide-rail 321 adjacent to each locking portion 322 extends away from the resisting portion 325, and each locking portion 322 is between the resisting portion 325 and the corresponding slide-rail 321. Alternatively, the restriction member 32 may form one slide-rail 321 and one locking portion 322.

The resilient member 33 is received in the receiving cutout 323 of the restriction member 32 with one end in the hole of the fixing portion 316 of the bracket 31 and the other end in the connection hole 324 of the restriction member 32. In the illustrated embodiment, the resilient member 33 is an extension spring. Alternatively, the resilient member 33 may be a compression spring, and the slide-rails 321 extend adjacent to the resisting portion 325, with each slide-rail 321 formed between the resisting portion 325 and the corresponding locking portion 322. Furthermore, one end of the resilient member 33 may be fixed on the fixing portion 316 and the other end fixed on one end of the receiving cutout 323 adjacent to the slide-rails 321. At this state, the resilient member 33 is a compression spring. One end of each slide-rail 321 adjacent to the locking portions 322 extends away from the resisting portion 325 with each locking portion 322 formed between the resisting portion 325 and the corresponding slide-rail 321. Conversely, the resilient member 33 is an extension spring, and one end of each slide-rail 321 adjacent to the locking portions 322 extends adjacent to the resisting portion 325, with each slide-rail 321 formed between the resisting portion 325 and the corresponding locking portion 322.

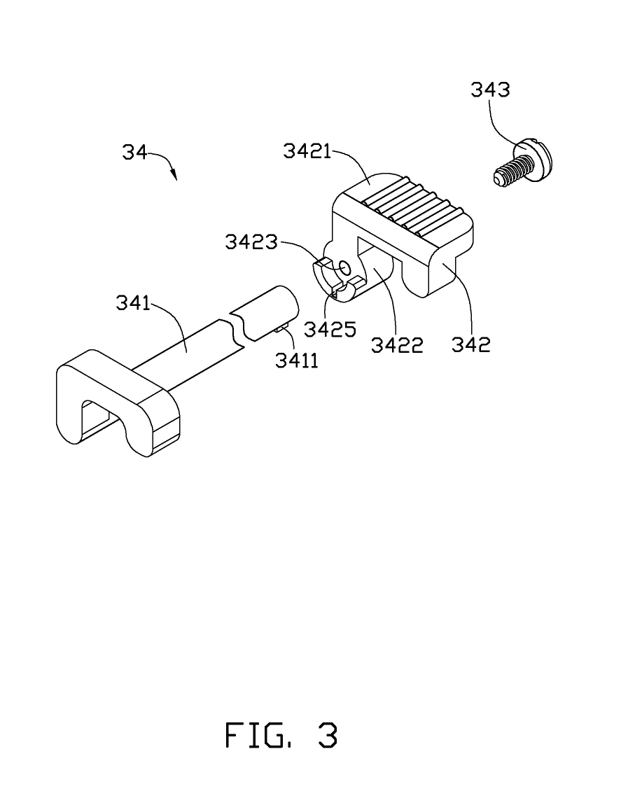

Also referring to FIG. 3, the release assembly 34 includes a pivot shaft 341, a contact member 342 biasing one end of the pivot shaft 341, and a fastener 343 locked on the contact member 342. The pivot shaft 341 forms a tongue 3411 protruding from an exterior surface of the distal end of the pivot shaft 341. The pivot shaft 341 further defines a threaded hole (not shown) in the distal end to receive the fastener 343. The contact member 342 includes an operating portion 3421 and a rotary portion 3422 connected with the operating portion 3421. The rotary portion 3422 defines a through hole 3423 through which the fastener 343 passes and a blocking groove 3425 therein to receive the tongue 3411 of the pivot shaft 341, such that the contact member 342 is non-rotatably connected to the pivot shaft 341. Alternatively, the pivot shaft 341 may define a blocking groove 3425, receiving a tongue 3411 formed by the rotary portion 3422 of the contact member 342.

Referring to FIGS. 1 through 3, during assembly of the securing mechanism 30, the pivot shaft 341 of the release assembly 34 passes through the shaft holes in the assembly portions 318 of the bracket 31, and extends out of the bracket 31. The contact member 342 biases the tongue 34, and the fastener 343 passes through the through hole 3423 in the contact member 342 and locks with the distal end of the pivot shaft 341. The restriction member 32 is movably held on the bracket 31 by the tabs 315 of the bracket 31 and is substantially perpendicular to the guide slits 311, with one end of each slide-rail 321 away from the locking portions 322 communicating with the corresponding guide slit 311 in the bracket 31. The resilient member 33 is positioned in the receiving cutout 323 of the restriction member 32, with one end connected to the fixing portion 316 of the bracket 31 and the other end received in the connection hole 324 in the restriction member 32. In the securing mechanism 30, the operating portion 3421 of the contact member 342 resists the resisting portion 325 of the restriction member 32. The securing mechanism 30 is fixed in the housing 10 adjacent to the opening therein, such that the component 20 can be installed into the securing mechanism 30.

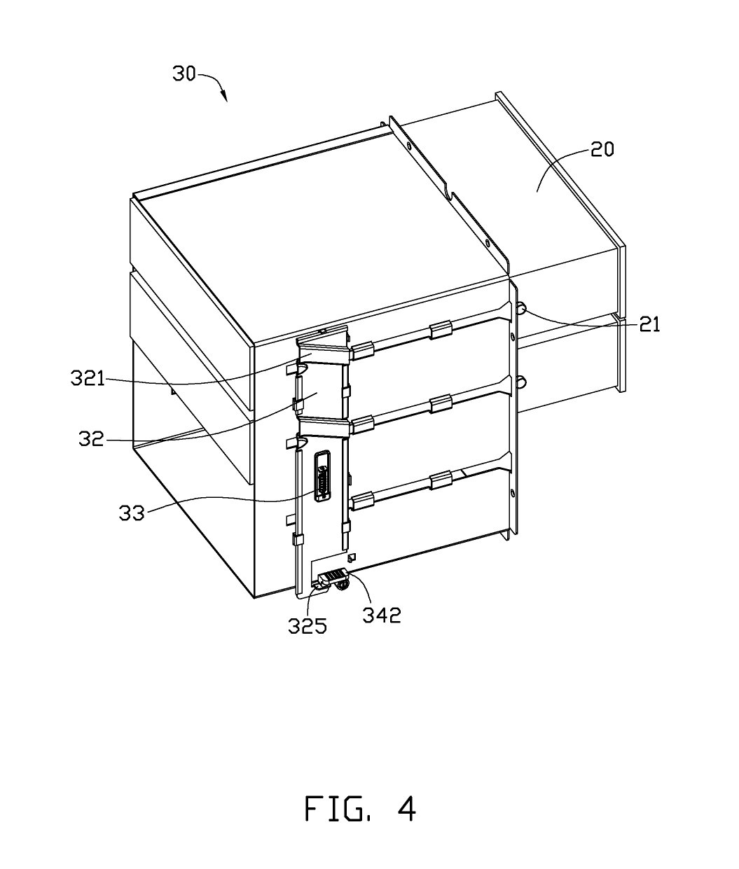

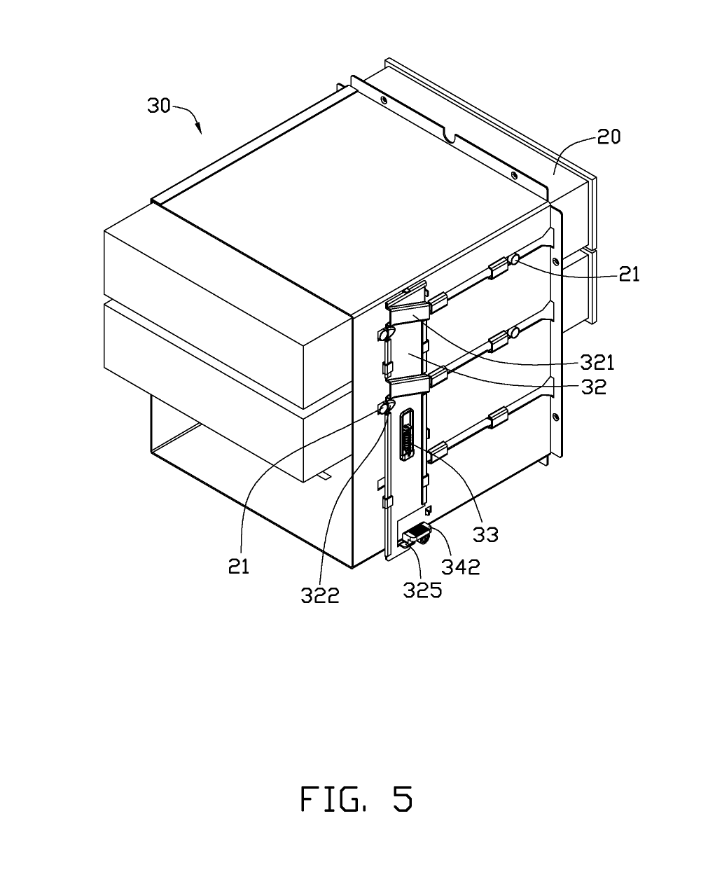

Also referring to FIG. 4, during installation of the component 20 into the securing mechanism 30, the protrusions 21 of the component 20 are received in and slide along the guide slits 311 in the bracket 31. When the first two protrusions 21 slide into the slide-rails 321 of the restriction member 32, the protrusions 21 slide in both the guide slits 311 and the slide-rails 321, such that the restriction member 32 slides towards the contact member 342 along the longitudinal axis thereof, and the resilient member 33 is deformed elastically. When the protrusions 21 slide out of the slide-rails 321, the restriction member 32 slides away from the contact member 342 along the longitudinal axis thereof driven by elastic force of the resilient member 33, and the locking portions 322 lock with the protrusions 21 of the component 20, and the component 20 is securely held in the securing mechanism 30 (shown in FIG. 5).

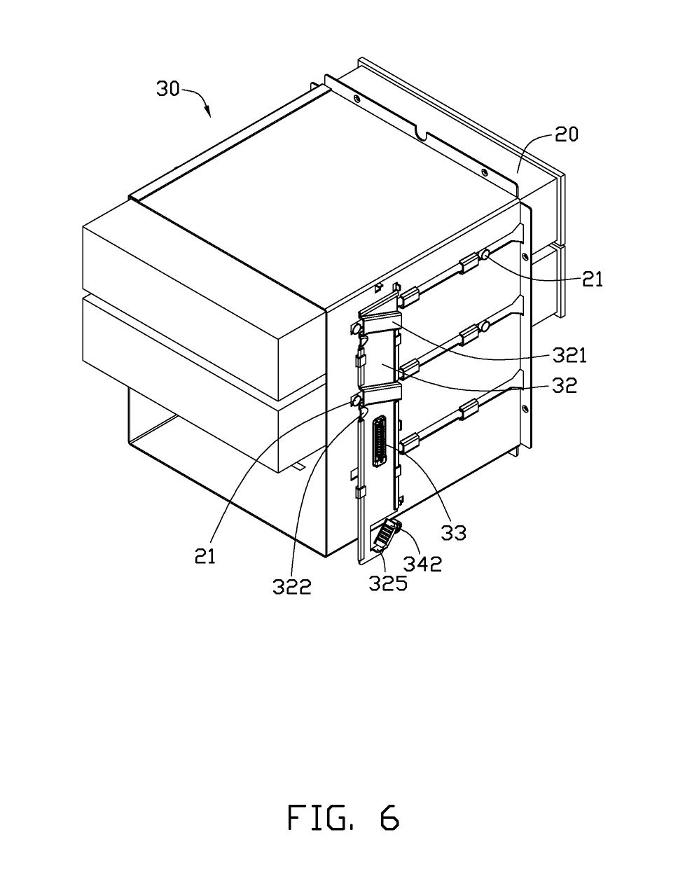

Also referring to FIG. 6, during disassembly of the component 20 from the securing mechanism 30, the operating portion 3421 of the contact member 34 is rotated around the pivot shaft 341, until the restriction member 32 slides towards the contact member 342 along the longitudinal axis again. The locking portions 322 release the protrusions 21 of the component 20, and one end of each slide-rail 321 adjacent to the locking portions 322 communicates with the corresponding guide slit 311 in the bracket 31. The component 20 is drawn to slide in both the guide slits 311 and the slide-rails 321 along the guide slits 311, such that the restriction member 32 slides away from the contact member 342 along the longitudinal axis thereof to an original state. The component 20 is further drawn out of the securing mechanism 30.

The securing mechanism 30 holds or releases the component 20 by the engagement of the locking portions 322 and the protrusions 21 during the slide of the restriction member 32. Therefore, the securing mechanism 30 has a simple and compact structure and a low manufacturing cost. In addition, the component 20 is easily installed into or disassembled from the securing mechanism 30.

The release assembly 34 may be omitted, and the resisting portion 325 of the restriction member 323 contacted directly to slide.

It is believed that the present embodiments and their advantages will be understood from the foregoing description, and it will be apparent that various changes may be made thereto without departing from the spirit and scope of the disclosure or sacrificing all of its material advantages.

What is claimed is:

1. A securing mechanism for a component in an electronic device enclosure, the component forming at least one protrusion thereon, the securing mechanism comprising:
a bracket defining at least one guide slit for receiving the at least one protrusion of the component;
a restriction member movably mounted on the bracket, the restriction member forming at least one slide-rail in which the at least one protrusion of the component slides is received and at least one locking portion adjacent to the at least one slide-rail, wherein the at least one slide-rail is oblique relative to the at least one guide slit in the bracket; and
a resilient member connected to the bracket and the restriction member;
wherein when the at least one protrusion slides along the at least one slide-rail, the restriction member moves substantially perpendicular to the at least one guide slit and the resilient member is deformed elastically, and an elastic force of the resilient member drives the at least one locking portion to lock with the at least one protrusion when the at least one protrusion slides out of the at least one slide-rail.

2. The securing mechanism of claim 1, wherein the bracket forms at least one pair of tabs adjacent to an end of the at least one guide slit.

3. The securing mechanism of claim 1, wherein the bracket forms a fixing portion, to which one end of the resilient member is connected.

4. The securing mechanism of claim 3, wherein one end of the at least one slide-rail communicates with the at least one guide slit when the resilient member is at a relaxed state, and the other end of the at least one side-rail is at one side of the at least one guide slit.

5. The securing mechanism of claim 3, wherein the restriction member defines a receiving cutout for receiving the resilient member.

6. The securing mechanism of claim 1, further comprising a release assembly, wherein the restriction member forms a resisting portion locking with the release assembly.

7. The securing mechanism of claim 6, wherein the release assembly comprises a contact member resisting the resisting portion.

8. The securing mechanism of claim 7, wherein the release assembly further comprises a pivot shaft fixedly connected with the contact member, and the bracket forms at least one assembly portion defining a shaft hole through which the pivot shaft passes.

9. The securing mechanism of claim 8, wherein the pivot shaft forms a tongue, and the contact member comprises a rotary portion defining a blocking groove engaging with the tongue.

10. The securing mechanism of claim 8, wherein release assembly further comprises a fastener, and the contact member further defines a through hole through which the fastener passes.

11. The securing mechanism of claim 1, wherein the bracket forms at least one reinforcement portion connecting two sides of the at least one guide slit.

12. An electronic device enclosure for a component, the component forming at least one protrusion thereon, the enclosure comprising:
a housing defining an opening;
a securing mechanism for the component, the securing mechanism being fixed in the housing through the opening in the housing and comprising:
a bracket defining at least one guide slit receiving the at least one protrusion;
a restriction member movably receiving the bracket, the restriction member forming at least one slide-rail in which the at least one protrusion slides and at least one locking portion adjacent to the at least one slide-rail, the at least one slide-rail being oblique relative to the at least one guide slit; and
a resilient member connected to the bracket and the restriction member;
wherein when the at least one protrusion of the component slides along the at least one slide-rail, the restriction member moves substantially perpendicular to the at least one guide slit and the resilient member is deformed elastically, and an elastic force of the resilient member drives the at least one locking portion to lock with the at least one protrusion when the at least one protrusion slides out of the at least one slide-rail.

13. The electronic device enclosure of claim 12, wherein the bracket forms at least one pair of tabs adjacent to an end of the at least one guide slit.

14. The electronic device enclosure of claim 12, wherein the bracket forms a fixing portion, and one end of the resilient member is connected to the fixing portion.

15. The electronic device enclosure of claim 14, wherein one end of the at least one slide-rail communicates with the at least one guide slit when the resilient member is at a relaxed state, and the other end of the at least one side-rail is at one side of the at least one guide slit.

16. The electronic device enclosure of claim 14, wherein the restriction member defines a receiving cutout for receiving the resilient member.

17. The electronic device enclosure of claim 12, further comprising a release assembly comprising a contact member, wherein the restriction member forms a resisting portion locking with the contact member.

18. The electronic device enclosure of claim 17, wherein the release assembly further comprises a pivot shaft fixedly connected with the contact member, and the bracket forms at least one assembly portion defining a shaft hole through which the pivot shaft passes.

19. The electronic device enclosure of claim 18, wherein the pivot shaft forms a tongue, and the contact member comprises a rotary portion defining a blocking groove engaging with the tongue.

20. The electronic device enclosure of claim 12, wherein the bracket forms at least one reinforcement portion connecting two sides of the at least one guide slit.
